(19) United States
(12) Patent Application Publication
(10) Pub. No.: US 2026/0150353 A1
(43) Pub. Date: May 28, 2026

(54) SEMICONDUCTOR DEVICE

(71) Applicant: KABUSHIKI KAISHA TOSHIBA, Tokyo (JP)

(72) Inventors: Tomoaki INOKUCHI, Yokohama Kanagawa (JP); Shotaro BABA, Kawasaki Kanagawa (JP); Hiroki NEMOTO, Meguro Tokyo (JP); Hiro GANGI, Marugame Kagawa (JP); Taichi FUKUDA, Yokohama Kanagawa (JP); Yusuke KOBAYASHI, Yokohama Kanagawa (JP)

(73) Assignee: KABUSHIKI KAISHA TOSHIBA, Tokyo (JP)

(21) Appl. No.: 19/270,537

(22) Filed: Jul. 16, 2025

(30) Foreign Application Priority Data
Nov. 28, 2024 (JP) 2024-207520

(51) Int. Cl. H10D 62/10; H10D 62/60; H10D 64/00; H10D 64/23; H10D 64/27; H10D 64/62; H10D 64/64

(52) U.S. Cl. CPC H10D 62/126; H10D 62/60; H10D 64/112; H10D 64/117; H10D 64/256; H10D 64/513; H10D 64/62; H10D 64/647

(57) ABSTRACT

According to one embodiment, a semiconductor device includes first to third electrodes, a semiconductor member, and a first insulating member. The second electrode includes a first electrode portion and a second electrode portion. A direction from the first electrode to the first electrode portion is along a first direction. The second electrode portion is electrically connected to the first electrode portion. The semiconductor member includes a first semiconductor region of a first conductivity type. The first semiconductor region includes first to third partial regions. The first semiconductor region includes at least one of a fourth partial region or a fifth partial region. At least a part of the fourth partial region is between the third electrode and the first electrode portion in the first direction. At least a part of the fifth partial region is between the second electrode portion and the first electrode portion in the first direction.

### CROSS-REFERENCE TO RELATED APPLICATIONS

This application is based upon and claims the benefit of priority from Japanese Patent Application No. 2024-207520, filed on Nov. 28, 2024; the entire contents of which are incorporated herein by reference.

### FIELD

Embodiments described herein relate generally to a semiconductor device.

### BACKGROUND

For example, stable characteristics are desired in semiconductor devices.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a part of the semiconductor device according to the first embodiment;

FIG. 3 is a schematic perspective view illustrating the semiconductor device according to the first embodiment;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to the first embodiment;

FIG. 7 is a schematic cross-sectional view illustrating a semiconductor device according to the first embodiment;

FIG. 8 is a schematic cross-sectional view illustrating a semiconductor device according to the first embodiment; and

FIG. 9 is a schematic cross-sectional view illustrating a semiconductor device according to a second embodiment.

### DETAILED DESCRIPTION

According to one embodiment, a semiconductor device includes a first electrode, a second electrode, a third electrode, a semiconductor member, and a first insulating member. The second electrode includes a first electrode portion and a second electrode portion. A direction from the first electrode to the first electrode portion is along a first direction. The second electrode portion is electrically connected to the first electrode portion. The semiconductor member includes a first semiconductor region of a first conductivity type. The first semiconductor region includes a first partial region, a second partial region, and a third partial region. The first partial region is between the first electrode and the third electrode in the first direction. The second partial region is between the first electrode and the second electrode portion in the first direction. The third partial region is between at least a part of the second electrode portion and the third electrode in a second direction crossing the first direction. The first semiconductor region includes at least one of a fourth partial region or a fifth partial region. At least a part of the fourth partial region is between the third electrode and the first electrode portion in the first direction. At least a part of the fifth partial region is between the second electrode portion and the first electrode portion in the first direction. The first insulating member is provided between the third electrode and the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

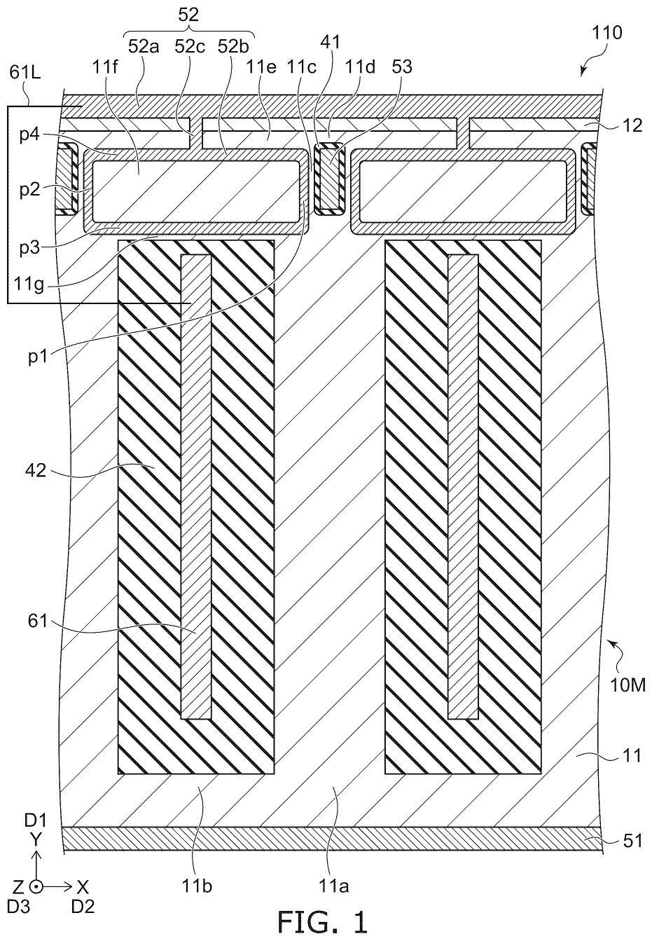

FIG. 1 is a schematic cross-sectional view illustrating a semiconductor device according to the first embodiment.

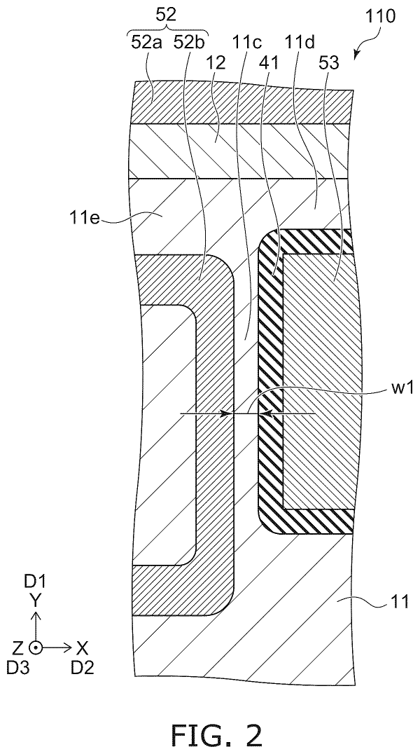

FIG. 2 is a schematic cross-sectional view illustrating a part of the semiconductor device according to the first embodiment.

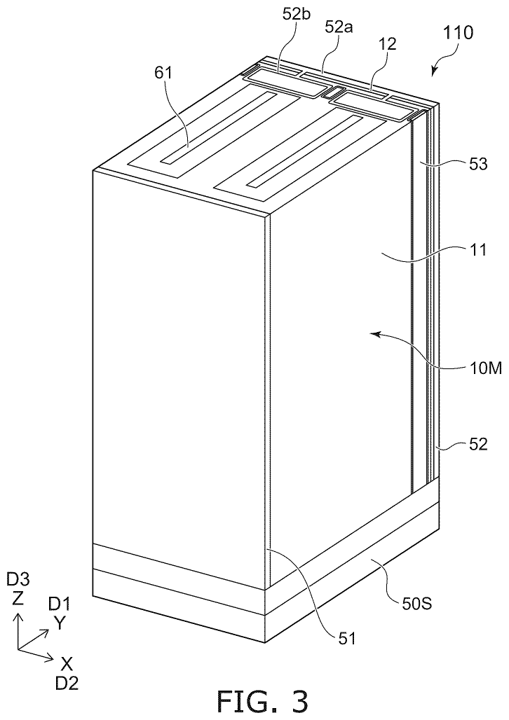

FIG. 3 is a schematic perspective view illustrating the semiconductor device according to the first embodiment.

As shown in FIG. 1, a semiconductor device 110 according to the embodiment includes a first electrode 51, a second electrode 52, a third electrode 53, a semiconductor member 10M, and a first insulating member 41.

The second electrode 52 includes a first electrode portion 52a and a second electrode portion 52b. A direction from the first electrode 51 to the first electrode portion 52a is along a first direction D1. The first direction D1 is defined as a Y-axis direction. A direction perpendicular to the Y-axis direction is defined as an X-axis direction. A direction perpendicular to the Y-axis direction and the X-axis direction is defined as a Z-axis direction.

The second electrode portion 52b is electrically connected to the first electrode portion 52a.

The semiconductor member 10M includes a first semiconductor region 11 of a first conductivity type. The first conductivity type is one of n-type and p-type. For example, the first conductivity type may be n-type.

The first semiconductor region 11 includes a first partial region 11a, a second partial region 11b, and a third partial region 11c. The first partial region 11a is located between the first electrode 51 and the third electrode 53 in the first direction D1. The second partial region 11b is located between the first electrode 51 and the second electrode portion 52b in the first direction D1. The third partial region 11c is located between at least a part of the second electrode portion 52b and the third electrode 53 in a second direction D2. The second direction D2 crosses the first direction D1. The second direction D2 may be, for example, the X-axis direction.

For example, a direction from at least a part of the second electrode portion 52b to at least a part of the third electrode 53 is along the second direction D2. A direction from the second partial region 11b to the first partial region 11a is along the second direction D2.

In this example, the first semiconductor region 11 includes at least one of the fourth partial region 11d or the fifth partial region 11e. At least a part of the fourth partial region 11d is located between the third electrode 53 and the first electrode portion 52a in the first direction D1. At least a part of the fifth partial region 11e is located between the second electrode portion 52b and the first electrode portion 52a in the first direction D1.

The first insulating member 41 is provided between the third electrode 53 and the semiconductor member 10M. The first insulating member 41 electrically insulates the third electrode 53 from the semiconductor member 10M. For example, a part of the first insulating member 41 is provided between the third partial region 11c and the third electrode 53. For example, another part of the first insulating member 41 is provided between the third electrode 53 and the fourth partial region 11d.

Current flowing between the first electrode 51 and the second electrode 52 can be controlled by a potential of the third electrode 53. The potential of the third electrode 53 may be, for example, a potential based on a potential of the second electrode 52. The first electrode 51 functions, for example, as a drain electrode. The second electrode 52 functions, for example, as a source electrode. The third electrode 53 functions, for example, as a gate electrode. The semiconductor device 110 is, for example, a transistor.

For example, the thickness of the depletion layer formed between the third partial region 11c and the second electrode 52 is controlled by the potential of the third electrode 53. For example, the third partial region 11c becomes at least a part of the channel.

In the embodiment, as described above, at least one of the fourth partial region 11d or the fifth partial region 11e is provided. This allows the desired structure to be obtained stably. For example, the third partial region 11c having a stable shape is easily obtained. The relative positional relationship between the third electrode 53 and the third partial region 11c is stabilized. For example, the relative positional relationship between the second electrode portion 52b and the third partial region 11c is stabilized. For example, high adhesion is easily obtained in the film that becomes the second electrode portion 52b. For example, the quality of the second electrode portion 52b is easily stabilized. According to the embodiment, a semiconductor device that can obtain stable characteristics can be provided.

For example, since the second electrode portion 52b is in Schottky contact with the first semiconductor region 11, better recovery characteristics can be obtained compared to a reference example that does not use a Schottky barrier. For example, a short gate length can be applied, resulting in a small gate capacitance. The process is simple, and stable characteristics can be easily obtained.

For example, the second electrode portion 52b includes at least one selected from the group consisting of Ti, W, Mo, Ta, Zr, Al, Sn, V, Re, Os, Ir, Pt, Pd, Rh, Ru, Nb, Sr, and Hf. Meanwhile, the semiconductor member 10M may include silicon. The second electrode portion 52b made of the above material makes it easy to obtain a stable Schottky contact.

The first electrode portion 52a may include a material included in the second electrode portion 52b. The material of the first electrode portion 52a may be substantially the same as the material of the second electrode portion 52b.

As shown in FIG. 1, in this example, the second electrode 52 further includes a third electrode portion 52c. The third electrode portion 52c electrically connects the second electrode portion 52b to the first electrode portion 52a. In this example, at least a part of the third electrode portion 52c is located between a part of the first semiconductor region 11 and another part of the first semiconductor region 11. The material of the third electrode portion 52c may be substantially the same as the material of the second electrode portion 52b.

The first electrode portion 52a, the second electrode portion 52b, and the third electrode portion 52c may be formed collectively.

As shown in FIG. 1, the semiconductor member 10M may further include a second semiconductor region 12 of a first conductivity type. At least a part of the second semiconductor region 12 is provided between the first electrode portion 52a and at least one of the fourth partial region 11d or the fifth partial region 11e in the first direction D1. A second impurity concentration of the first conductivity type in the second semiconductor region 12 is higher than a first impurity concentration of the first conductivity type in the first semiconductor region 11. This makes it possible to reduce the electrical resistance between the second electrode 52 and the first semiconductor region 11. For example, a low on-resistance can be obtained.

In one example, the first impurity concentration is, for example, not less than 1×10¹⁴ cm⁻³ and not more than 1×10¹⁷ cm⁻³. The second impurity concentration is not less than 1×10¹⁸ cm⁻³ and not more than 1×10²² cm⁻³.

As shown in FIG. 1, at least a part of the second semiconductor region 12 may be in contact with the first electrode portion 52a. Low electrical resistance is easily obtained.

As shown in FIG. 1, the second electrode portion 52b may include a first portion p1 and a second portion p2. The first portion p1 is located between the second portion p2 and the third electrode 53 in the second direction D2. The third partial region 11c is located between the first portion p1 and the third electrode 53 in the second direction D2.

The first semiconductor region 11 may further include a sixth partial region 11f. The sixth partial region 11f is located between the second portion p2 and the first portion p1 in the second direction D2.

The second electrode portion 52b may include a third portion p3 and a fourth portion p4. The third portion p3 is located between the first electrode 51 and the first electrode portion 52a in the first direction D1. The fourth portion p4 is located between the third portion p3 and the first electrode portion 52a in the first direction D1. The sixth partial region 11f is located between the third portion p3 and the fourth portion p4 in the first direction D1.

The third portion p3 may be continuous with the first portion p1 and the second portion p2. The fourth portion p4 may be continuous with the first portion p1 and the second portion p2. For example, in a plane including the first direction D1 and the second direction D2, the first portion p1, the second portion p2, the third portion p3, and the fourth portion p4 are provided around the sixth partial region 11f. For example, in a plane including the first direction D1 and the second direction D2, the sixth partial region 11f may be surrounded by the second electrode portion 52b.

As shown in FIG. 1, the semiconductor device 110 may further include a first conductive member 61 and a second insulating member 42. The first conductive member 61 is electrically connected to the second electrode 52. For example, the first conductive member 61 may be electrically connected to the second electrode 52 by a first wiring 61L or the like at a position different from that of the cross section of FIG. 1.

A position of the first conductive member 61 in the first direction D1 (first conductive member position) is between a position of the first electrode 51 in the first direction D1 (first electrode position) and a position of the second electrode portion 52b in the first direction D1 (second electrode portion position). The second insulating member 42 is located between the first conductive member 61 and the first semiconductor region 11. For example, the second insulating member 42 electrically insulates between the first conductive member 61 and the first semiconductor region 11.

Such a first conductive member 61 reduces the concentration of the electric field. For example, a high break down voltage is easily obtained. Stable operation is easily obtained. The first conductive member 61 functions as a field plate, for example.

As shown in FIG. 1, the first semiconductor region 11 may include a seventh partial region 11g. At least a part of the seventh partial region 11g is located between the second insulating member 42 and the second electrode portion 52b. By providing the seventh partial region 11g, the second electrode portion 52b can be formed more stably. For example, high adhesion is easily obtained in the metal that becomes the second electrode portion 52b.

In FIG. 2, a part of FIG. 1 is shown enlarged. A length of the third partial region 11c along the second direction D2 is defined as a third partial region width w1. The threshold voltage can be controlled by the third partial region width w1. If the third partial region width w1 is large, the threshold voltage will be low. In the embodiment, the third partial region width w1 may be, for example, not less than 20 nm and not more than 80 nm. A practical threshold voltage can be obtained.

As shown in FIG. 3, the semiconductor device 110 may include a base 50S. A third direction D3 from the base 50S to the first electrode 51, the second electrode 52, and the semiconductor member 10M crosses a plane including the first direction D1 and the second direction D2. The third direction D3 is, for example, the Z-axis direction. The third electrode 53 extends, for example, along the third direction D3. The first electrode 51 is along the X-Z plane. The first electrode portion 52a of the second electrode 52 is along the X-Z plane.

With the configuration illustrated in FIG. 3, for example, the semiconductor device 110 can be formed by a simple process. For example, a hole (trench) corresponding to the second electrode portion 52b is formed in the semiconductor layer that becomes the semiconductor member 10M. The second electrode portion 52b is obtained by forming a metal film inside the hole. In forming the second electrode portion 52b, the first electrode portion 52a may be formed at the same time.

In the semiconductor device 110, a plurality of third electrodes 53 may be provided. The plurality of third electrodes 53 are arranged along the second direction D2. A plurality of first conductive members 61 may be provided. The plurality of first conductive members 61 are arranged along the second direction D2.

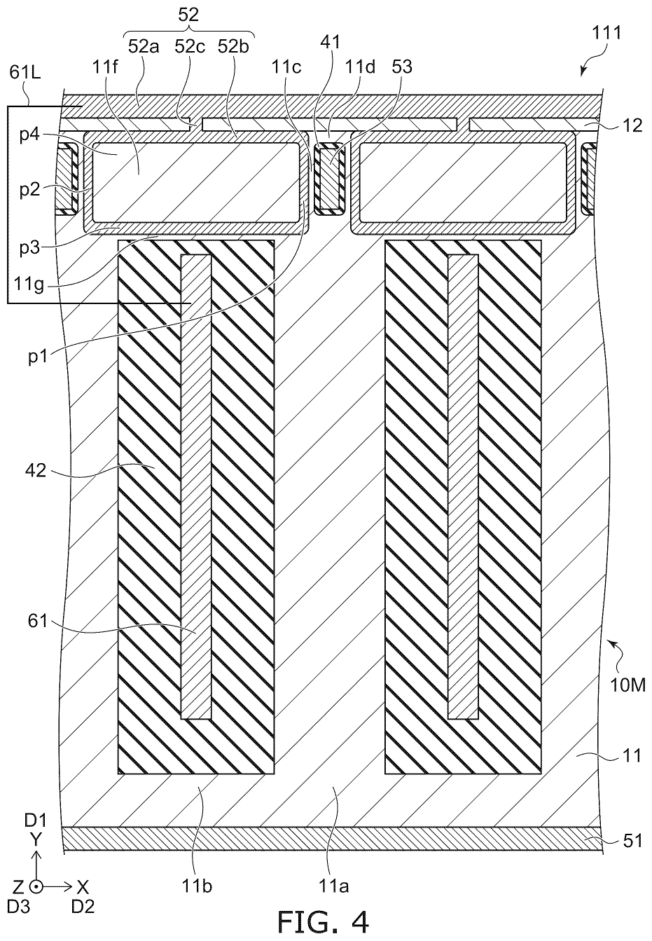

FIG. 4 is a schematic cross-sectional view illustrating a semiconductor device according to the first embodiment.

As shown in FIG. 4, in a semiconductor device 111 according to the embodiment, the first semiconductor region 11 includes the fourth partial region 11d and does not include the fifth partial region 11e. Except for this, the configuration of the semiconductor device 111 may be the same as the configuration of the semiconductor device 110. In such a semiconductor device 111, the relative positional relationship between the third electrode 53 and the third partial region 11c is stabilized. The desired structure is stably obtained. A semiconductor device capable of obtaining stable characteristics can be provided.

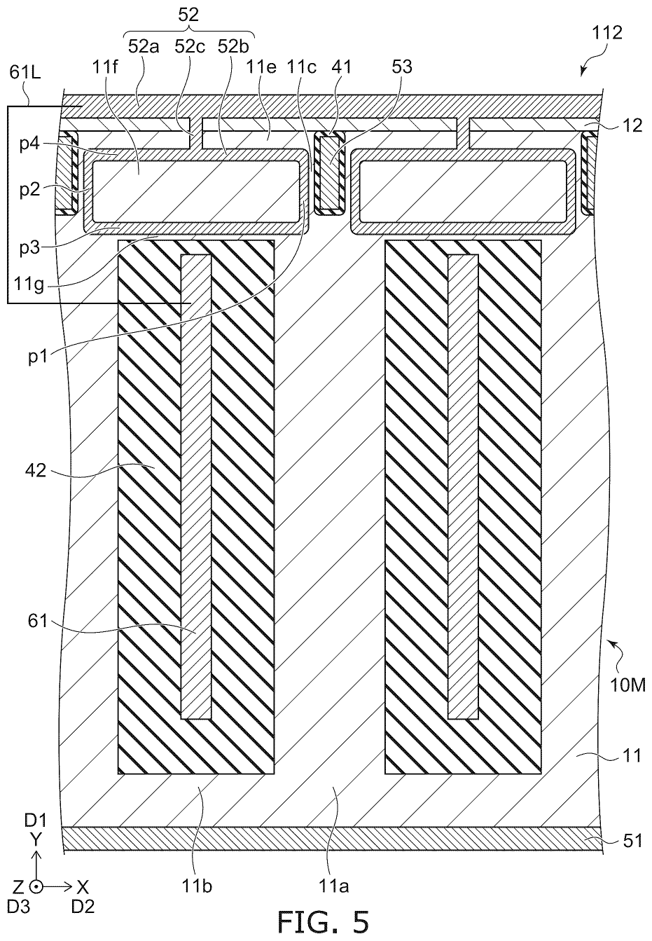

FIG. 5 is a schematic cross-sectional view illustrating a semiconductor device according to the first embodiment.

As shown in FIG. 5, in a semiconductor device 112 according to the embodiment, the first semiconductor region 11 includes the fifth partial region 11e and does not include the fourth partial region 11d. Except for this, the configuration of the semiconductor device 112 may be the same as the configuration of the semiconductor device 110. In such a semiconductor device 112, for example, the relative positional relationship between the second electrode portion 52b and the third partial region 11c is stabilized. For example, the quality of the second electrode portion 52b is easy to be stabilized. A semiconductor device capable of obtaining stable characteristics can be provided.

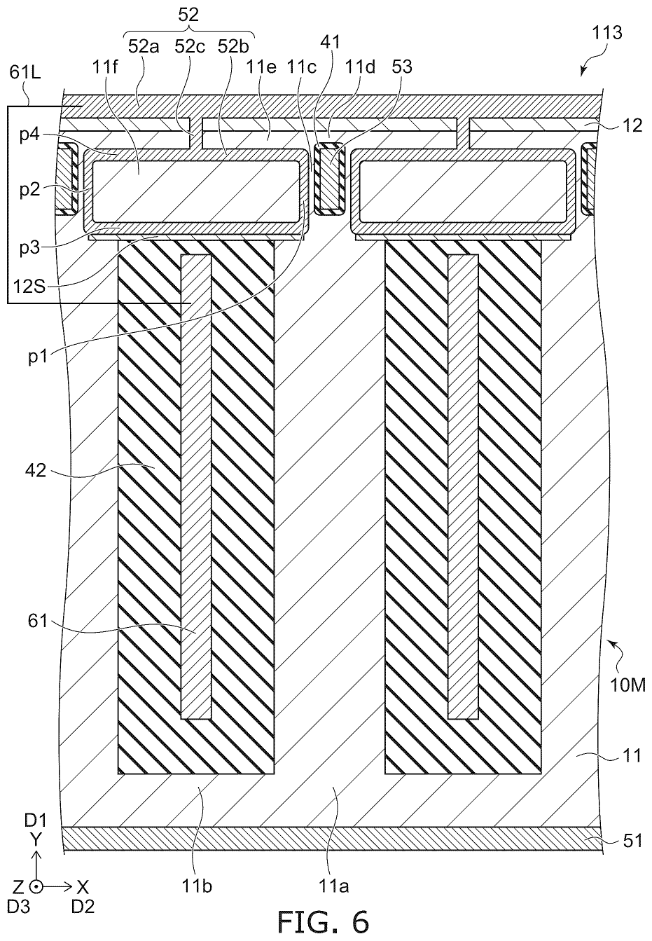

FIG. 6 is a schematic cross-sectional view illustrating a semiconductor device according to the first embodiment.

As shown in FIG. 6, a semiconductor device 113 according to the embodiment includes the second silicide member 12S. Except for this, the configuration of the semiconductor device 113 may be the same as the configuration of the semiconductor device 110.

In the semiconductor device 113, at least a part of the second silicide member 12S is located between the second insulating member 42 and the second electrode portion 52b. Thus, the second silicide member 12S may be provided at the position of the seventh partial region 11g in the semiconductor device 110. The desired structure can also be stably obtained in the semiconductor device 114. A semiconductor device that can obtain stable characteristics can be provided.

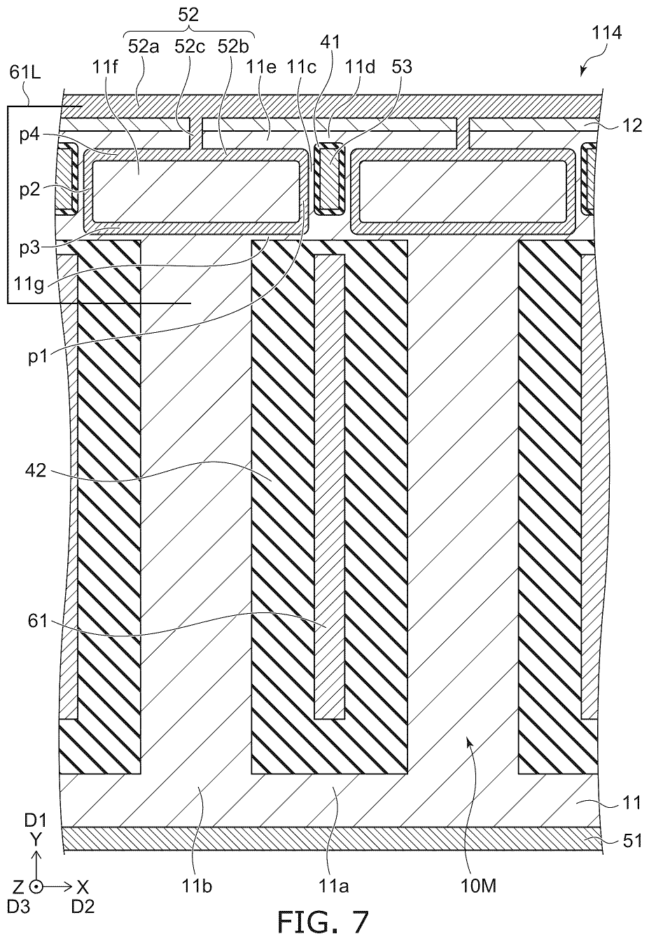

FIG. 7 is a schematic cross-sectional view illustrating a semiconductor device according to the first embodiment.

As shown in FIG. 7, in a semiconductor device 114 according to the embodiment, the configuration of the first conductive member 61 is different from that in the semiconductor device 110. Except for this, the configuration of the semiconductor device 114 may be the same as the configuration of the semiconductor device 110.

In the semiconductor device 114, at least a part of the first conductive member 61 is located between the first electrode 51 and the third electrode 53 in the first direction D1. In the embodiment, the positional relationship between the first conductive member 61 and the third electrode 53 in the second direction D2 is arbitrary. In the embodiment, the positional relationship between the first conductive member 61 and the second electrode portion 52b in the second direction D2 is arbitrary.

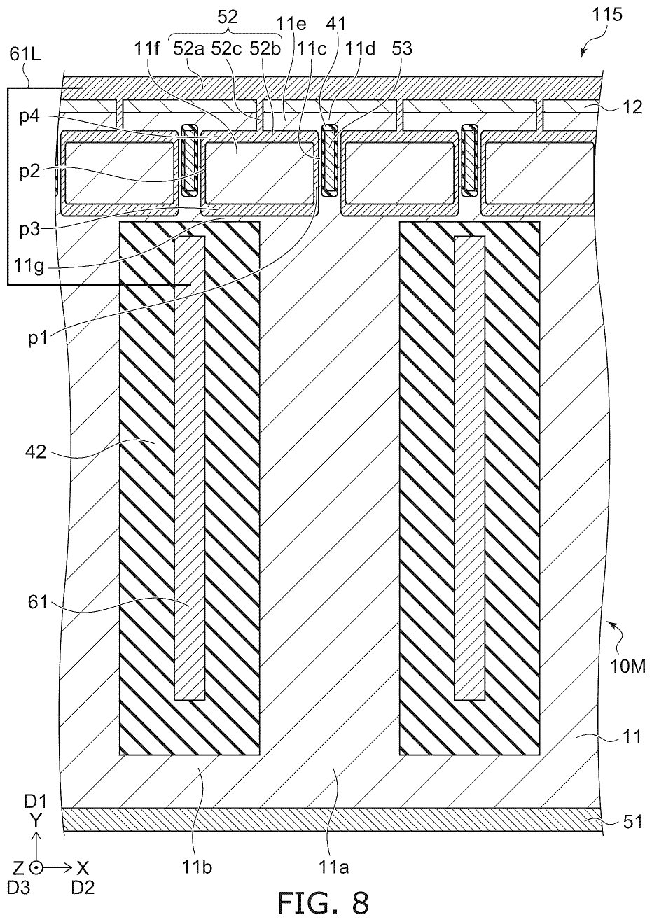

FIG. 8 is a schematic cross-sectional view illustrating a semiconductor device according to the first embodiment.

As shown in FIG. 8, in a semiconductor device 115 according to the embodiment, the configurations of the first conductive member 61 and the third electrode 53 are different from those in the semiconductor device 110. Except for this, the configuration of the semiconductor device 115 may be the same as the configuration of the semiconductor device 110.

In the semiconductor device 115, a plurality of third electrodes 53 are arranged along the second direction D2. A plurality of first conductive members 61 are arranged along the second direction D2. The pitch of the plurality of first conductive members 61 in the second direction D2 (first conductive member pitch) is different from the pitch of the plurality of third electrodes 53 in the second direction D2 (third electrode pitch). In the embodiment, the positional relationship between the third electrodes 53 and the first conductive members 61 can be modified in various ways.

### Second Embodiment

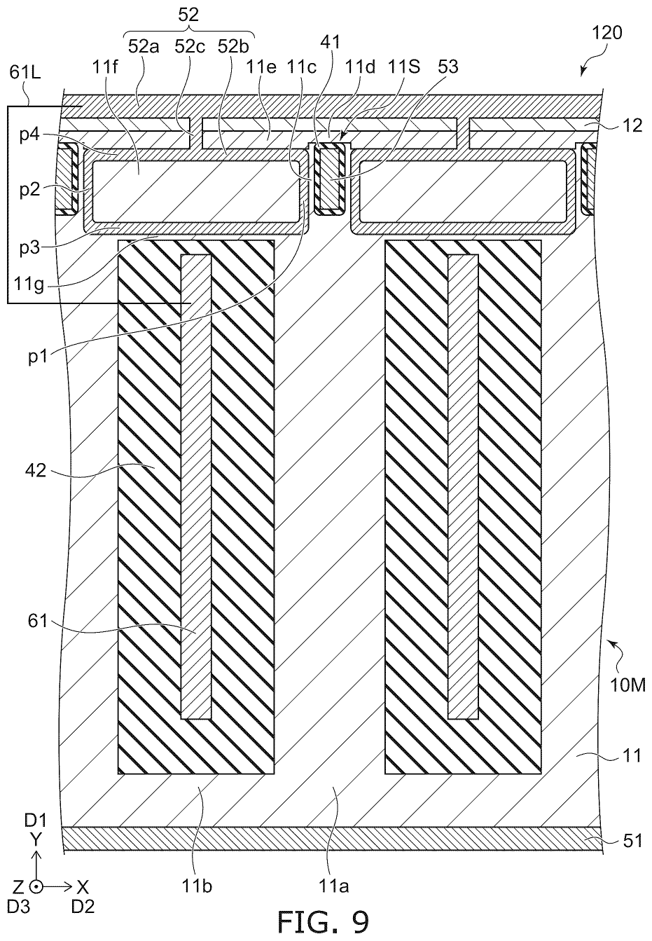

FIG. 9 is a schematic cross-sectional view illustrating a semiconductor device according to the second embodiment.

As shown in FIG. 9, a semiconductor device 120 according to the embodiment includes a first silicide member 11S. Except for this, the configuration of the semiconductor device 120 may be the same as the semiconductor device 110, etc.

In the semiconductor device 120, the first semiconductor region 11 of the semiconductor member 10M includes the first partial region 11a, the second partial region 11b, and the third partial region 11c. As already explained, the first partial region 11a is located between the first electrode 51 and the third electrode 53 in the first direction D1. The second partial region 11b is located between the first electrode 51 and the second electrode portion 52b in the first direction D1. The third partial region 11c is located between at least a part of the second electrode portion 52b and the third electrode 53 in the second direction D2 crossing the first direction D1.

The first silicide member 11S includes at least one of a fourth partial region 11d or a fifth partial region 11e. At least a part of the fourth partial region 11d is located between the third electrode 53 and the first electrode portion 52a in the first direction D1. At least a part of the fifth partial region 11e is located between the second electrode portion 52b and the first electrode portion 52a in the first direction D1.

In the embodiment, at least one of the fourth partial region 11d or the fifth partial region 11e may include a silicide. At least one of the fourth partial region 11d or the fifth partial region 11e may include a semiconductor of the first conductivity type. In the semiconductor device 113 as well, the desired structure can be stably obtained. A semiconductor device capable of obtaining stable characteristics can be provided.

In the semiconductor device 120, the configuration described in relation to the first embodiment may be applied. In the semiconductor device 120, for example, the second silicide member 12S may be provided. In the semiconductor device 120, for example, the configuration described in relation to the semiconductor device 114 or the semiconductor device 115 may be applied.

The embodiment may include the following technical proposals:

### Technical Proposal 1

A semiconductor device, comprising:
a first electrode;
a second electrode including a first electrode portion and a second electrode portion, a direction from the first electrode to the first electrode portion being along a first direction, the second electrode portion being electrically connected to the first electrode portion;
a third electrode;
a semiconductor member including a first semiconductor region of a first conductivity type, the first semiconductor region including a first partial region, a second partial region, and a third partial region, the first partial region being between the first electrode and the third electrode in the first direction, the second partial region being between the first electrode and the second electrode portion in the first direction, the third partial region being between at least a part of the second electrode portion and the third electrode in a second direction crossing the first direction, the first semiconductor region including at least one of a fourth partial region or a fifth partial region, at least a part of the fourth partial region being between the third electrode and the first electrode portion in the first direction, at least a part of the fifth partial region being between the second electrode portion and the first electrode portion in the first direction; and
a first insulating member provided between the third electrode and the semiconductor member.

### Technical Proposal 2

A semiconductor device, comprising:
a first electrode;
a second electrode including a first electrode portion and a second electrode portion, a direction from the first electrode to the first electrode portion being along a first direction, the second electrode portion being electrically connected to the first electrode portion;
a third electrode;
a semiconductor member including a first semiconductor region of a first conductivity type, the first semiconductor region including a first partial region, a second partial region, and a third partial region, the first partial region being between the first electrode and the third electrode in the first direction, the second partial region being between the first electrode and the second electrode portion in the first direction, the third partial region being between at least a part of the second electrode portion and the third electrode in a second direction crossing the first direction;
a first silicide member including at least one of a fourth partial region or a fifth partial region, at least a part of the fourth partial region being between the third electrode and the first electrode portion in the first direction, at least a part of the fifth partial region being located between the second electrode portion and the first electrode portion in the first direction; and
a first insulating member provided between the third electrode and the semiconductor member.

### Technical Proposal 3

The semiconductor device according to Technical proposal 1 or 2, wherein
current flowing between the first electrode and the second electrode is configured to be controllable by a potential of the third electrode.

### Technical Proposal 4

The semiconductor device according to any one of technical proposals 1-3, wherein
the second electrode portion is in Schottky contact with the first semiconductor region.

### Technical Proposal 5

The semiconductor device according to any one of Technical proposals 1-4, wherein
the second electrode portion includes at least one selected from the group consisting of Ti, W, Mo, Ta, Zr, Al, Sn, V, Re, Os, Ir, Pt, Pd, Rh, Ru, Nb, Sr, and Hf.

### Technical Proposal 6

The semiconductor device according to any one of Technical proposals 1-5, wherein
the first electrode portion includes the material included in the second electrode portion.

### Technical Proposal 7

The semiconductor device according to any one of Technical proposals 1-6, wherein
the semiconductor member further includes a second semiconductor region of the first conductivity type,
at least a part of the second semiconductor region is between the first electrode portion and at least one of the fourth partial region or the fifth partial region in the first direction, and
a second impurity concentration of the first conductivity type in the second semiconductor region is higher than a first impurity concentration of the first conductivity type in the first semiconductor region.

### Technical Proposal 8

The semiconductor device according to Technical proposal 7, wherein
at least a part of the second semiconductor region is in contact with the first electrode portion.

### Technical Proposal 9

The semiconductor device according to any one of technical proposals 1-8, wherein
the second electrode portion includes a first portion and a second portion,
the first portion is between the second portion and the third electrode in the second direction,
the third partial region is between the first portion and the third electrode in the second direction,
the first semiconductor region further includes a sixth partial region,
the sixth partial region is between the second portion and the first portion in the second direction.

### Technical Proposal 10

The semiconductor device according to Technical proposal 9, wherein
the second electrode portion includes a third portion and a fourth portion,
the third portion is between the first electrode and the first electrode portion in the first direction,
the fourth portion is between the third portion and the first electrode portion in the first direction, and
the sixth partial region is between the third portion and the fourth portion in the first direction.

### Technical Proposal 11

The semiconductor device according to Technical proposal 10, wherein
the third portion is continuous with the first portion and the second portion, and
the fourth portion is continuous with the first portion and the second portion.

### Technical Proposal 12

The semiconductor device according to any one of Technical proposals 1-11, wherein
the second electrode further includes a third electrode portion electrically connecting the second electrode portion to the first electrode portion.

### Technical Proposal 13

The semiconductor device according to Technical proposal 12, wherein
at least a part of the third electrode portion is between a part of the first semiconductor region and another part of the first semiconductor region.

### Technical Proposal 14

The semiconductor device according to any one of Technical proposals 1-13, further comprising:
a first conductive member electrically connected to the second electrode: and
a second insulating member,
a first conductive member position in the first direction of the first conductive member being between a first electrode position of the first electrode in the first direction and a second electrode portion position of the second electrode portion in the first direction, and
the second insulating member being between the first conductive member and the first semiconductor region.

### Technical Proposal 15

The semiconductor device according to Technical proposal 14, wherein
the first semiconductor region includes a seventh partial region, and
at least a part of the seventh partial region is between the second insulating member and the second electrode portion.

### Technical Proposal 16

The semiconductor device according to Technical proposal 14, further including:
a second silicide member,
at least a part of the second silicide member being between the second insulating member and the second electrode portion.

### Technical Proposal 17

The semiconductor device according to any one of Technical proposals 1-16, wherein
a width of the third partial region along the second direction is not less than 20 nm and not more than 80 nm.

### Technical Proposal 18

The semiconductor device according to Technical proposal 14 or 15, wherein
a plurality of the third electrodes are provided,
a plurality of the first conductive members are provided, and
a first conductive member pitch of the plurality of the first conductive members in the second direction is different from a third electrode pitch of the plurality of the third electrodes in the second direction.

### Technical Proposal 19

The semiconductor device according to any one of Technical proposals 1-18, further comprising:
a base,
a third direction from the base to the first electrode, the second electrode, and the semiconductor member crossings a plane including the first direction and the second direction.

### Technical Proposal 20

The semiconductor device according to Technical proposal 19, wherein the third electrode extends along the third direction.

According to the embodiment, a semiconductor device capable of obtaining stable characteristics is provided.

In the specification, “vertical” and “parallel” do not only mean strictly vertical and strictly parallel, but also include, for example, variations in the manufacturing process, and may mean substantially vertical and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode including a first electrode portion and a second electrode portion, a direction from the first electrode to the first electrode portion being along a first direction, the second electrode portion being electrically connected to the first electrode portion;
a third electrode;
a semiconductor member including a first semiconductor region of a first conductivity type, the first semiconductor region including a first partial region, a second partial region, and a third partial region, the first partial region being between the first electrode and the third electrode in the first direction, the second partial region being between the first electrode and the second electrode portion in the first direction, the third partial region being between at least a part of the second electrode portion and the third electrode in a second direction crossing the first direction, the first semiconductor region including at least one of a fourth partial region or a fifth partial region, at least a part of the fourth partial region being between the third electrode and the first electrode portion in the first direction, at least a part of the fifth partial region being between the second electrode portion and the first electrode portion in the first direction; and
a first insulating member provided between the third electrode and the semiconductor member.

2. A semiconductor device, comprising:
a first electrode;
a second electrode including a first electrode portion and a second electrode portion, a direction from the first electrode to the first electrode portion being along a first direction, the second electrode portion being electrically connected to the first electrode portion;
a third electrode;
a semiconductor member including a first semiconductor region of a first conductivity type, the first semiconductor region including a first partial region, a second partial region, and a third partial region, the first partial region being between the first electrode and the third electrode in the first direction, the second partial region being between the first electrode and the second electrode portion in the first direction, the third partial region being between at least a part of the second electrode portion and the third electrode in a second direction crossing the first direction;
a first silicide member including at least one of a fourth partial region or a fifth partial region, at least a part of the fourth partial region being between the third electrode and the first electrode portion in the first direction, at least a part of the fifth partial region being located between the second electrode portion and the first electrode portion in the first direction; and
a first insulating member provided between the third electrode and the semiconductor member.

3. The semiconductor device according to claim 1, wherein
current flowing between the first electrode and the second electrode is configured to be controllable by a potential of the third electrode.

4. The semiconductor device according to claim 1, wherein
the second electrode portion is in Schottky contact with the first semiconductor region.

5. The semiconductor device according to claim 1, wherein
the second electrode portion includes at least one selected from the group consisting of Ti, W, Mo, Ta, Zr, Al, Sn, V, Re, Os, Ir, Pt, Pd, Rh, Ru, Nb, Sr, and Hf.

6. The semiconductor device according to claim 1, wherein
the first electrode portion includes the material included in the second electrode portion.

7. The semiconductor device according to claim 1, wherein
the semiconductor member further includes a second semiconductor region of the first conductivity type,
at least a part of the second semiconductor region is between the first electrode portion and at least one of the fourth partial region or the fifth partial region in the first direction, and
a second impurity concentration of the first conductivity type in the second semiconductor region is higher than a first impurity concentration of the first conductivity type in the first semiconductor region.

8. The semiconductor device according to claim 7, wherein
at least a part of the second semiconductor region is in contact with the first electrode portion.

9. The semiconductor device according to claim 1, wherein
the second electrode portion includes a first portion and a second portion,
the first portion is between the second portion and the third electrode in the second direction,
the third partial region is between the first portion and the third electrode in the second direction,
the first semiconductor region further includes a sixth partial region,
the sixth partial region is between the second portion and the first portion in the second direction.

10. The semiconductor device according to claim 9, wherein
the second electrode portion includes a third portion and a fourth portion,
the third portion is between the first electrode and the first electrode portion in the first direction,
the fourth portion is between the third portion and the first electrode portion in the first direction, and
the sixth partial region is between the third portion and the fourth portion in the first direction.

11. The semiconductor device according to claim 10, wherein
the third portion is continuous with the first portion and the second portion, and
the fourth portion is continuous with the first portion and the second portion.

12. The semiconductor device according to claim 1, wherein
the second electrode further includes a third electrode portion electrically connecting the second electrode portion to the first electrode portion.

13. The semiconductor device according to claim 12, wherein
at least a part of the third electrode portion is between a part of the first semiconductor region and another part of the first semiconductor region.

14. The semiconductor device according to claim 1, further comprising:
a first conductive member electrically connected to the second electrode: and
a second insulating member,
a first conductive member position in the first direction of the first conductive member being between a first electrode position of the first electrode in the first direction and a second electrode portion position of the second electrode portion in the first direction, and
the second insulating member being between the first conductive member and the first semiconductor region.

15. The semiconductor device according to claim 14, wherein
the first semiconductor region includes a seventh partial region, and
at least a part of the seventh partial region is between the second insulating member and the second electrode portion.

16. The semiconductor device according to claim 14, further including:
a second silicide member,
at least a part of the second silicide member being between the second insulating member and the second electrode portion.

17. The semiconductor device according to claim 1, wherein
a width of the third partial region along the second direction is not less than 20 nm and not more than 80 nm.

18. The semiconductor device according to claim 14, wherein
a plurality of the third electrodes are provided,
a plurality of the first conductive members are provided, and
a first conductive member pitch of the plurality of the first conductive members in the second direction is different from a third electrode pitch of the plurality of the third electrodes in the second direction.

19. The semiconductor device according to claim 1, further comprising:
a base,
a third direction from the base to the first electrode, the second electrode, and the semiconductor member crossings a plane including the first direction and the second direction.

20. The semiconductor device according to claim 19, wherein the third electrode extends along the third direction.
